(19) United States
(12) Patent Application Publication
(10) Pub. No.: US 2025/0185370 A1
(43) Pub. Date: Jun. 5, 2025

(54) DISPLAY PANEL

(71) Applicant: HANNSTAR DISPLAY CORPORATION, Taipei City (TW)

(72) Inventors: Shao-Chien Chang, Taoyuan City (TW); Yen-Chung Chen, Taichung City (TW); Mu-Kai Kang, Tainan City (TW); Jing-Xuan Chen, Tainan City (TW); Qi-En Luo, Chiayi County (TW); Cheng-Yen Yeh, Taichung City (TW)

(73) Assignee: HANNSTAR DISPLAY CORPORATION, Taipei City (TW)

(21) Appl. No.: 18/822,447

(22) Filed: Sep. 2, 2024

(30) Foreign Application Priority Data
Nov. 30, 2023 (TW) 112146477

(51) Int. Cl. H01L 27/12

(52) U.S. Cl. CPC H10D 86/60; H10D 86/441

(57) ABSTRACT

This invention discloses a display panel includes a substrate and a sub-pixel. The sub-pixel is disposed on the substrate. The sub-pixel includes a transistor, and the transistor includes a gate, a semiconductor layer, a source, a drain, and a dummy electrode. The gate is disposed on the substrate. The semiconductor layer is disposed on the gate. The source and the drain are disposed on the semiconductor layer, the source is disposed at one end of the semiconductor layer, and the drain is disposed at the other end of the semiconductor layer. The dummy electrode is disposed on the semiconductor layer and between the source and the drain. The dummy electrode and the source are separated, the dummy electrode and the drain are separated, and the dummy electrode is electrically floating.

### BACKGROUND OF THE INVENTION

### 1. Field of the Invention

The present invention relates to a display panel, and particular to a display panel with a low electricity leakage transistor.

### 2. Description of the Prior Art

In high pixels per inch (PPI) display panels, sizes of transistors are constrained by small areas of each sub-pixel. Therefore, one of the objectives of the present invention is to effectively suppress electricity leakage under the condition of limited transistor sizes, so as to make the display panel equipped with a preferable display quality.

### SUMMARY OF THE INVENTION

The technical problem to be solved by the present invention is how to effectively suppress electricity leakage under the condition of limited transistor sizes so as to make the display panel equipped with a preferable display quality.

In order to solve the aforementioned technical problem, the present invention provides a display panel, wherein the display panel includes a substrate and a sub-pixel. The sub-pixel is disposed on the substrate, wherein the sub-pixel includes a transistor. The transistor includes a gate, a semiconductor layer, a source, a drain, and a dummy electrode. The gate is disposed on the substrate. The semiconductor layer is disposed on the gate. The source and the drain are disposed on the semiconductor layer, wherein the source is disposed at one end of the semiconductor layer, and the drain is disposed at another end of the semiconductor layer. The dummy electrode is disposed on the semiconductor layer and between the source and the drain, wherein the dummy electrode is separated from the source, the dummy electrode is separated from the drain, and the dummy electrode is electrically floating.

In the display panel of the present invention, the transistor of the sub-pixel includes the dummy electrode, wherein the dummy electrode is disposed between the source and the drain, which may increase a channel length of the transistor so as to suppress electricity leakage. Besides, a portion of the semiconductor layer may be shielded by the dummy electrode to reduce the leakage current generated by the semiconductor layer receiving light. In addition, although the transistor further includes the dummy electrode, an area of the transistor is not significantly increased, which preserves enough area in the sub-pixel to dispose a pixel electrode, such that the stored capacitance can be enough to prevent the display quality from being affected due to lack of capacitance during low frequency driving.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a top view of a sub-pixel of a display panel of the first embodiment of the present invention.

FIG. 2 is a schematic diagram illustrating an enlarged view of a transistor of a display panel of the first embodiment of the present invention.

FIG. 3 is a schematic diagram illustrating a cross-section view of a transistor of a display panel of the first embodiment of the present invention.

FIG. 4 is a schematic diagram illustrating an enlarged view of a transistor of a display panel of the second embodiment of the present invention.

### DETAILED DESCRIPTION

To provide a better understanding of the present invention to those skilled in this field, preferred embodiments will be detailed as follows. The preferred embodiments of the present invention are illustrated in the accompanying drawings to elaborate on the contents and effects to be achieved. It should be noted that the drawings are simplified schematics, and therefore show only the components and combinations associated with the present invention, to provide a clearer description of the primary architecture or method of implementation. The components would be complex in reality. In addition, for ease of explanation, the components shown in the drawings may not represent their actual number, shape, and dimensions; details can be adjusted according to design requirements.

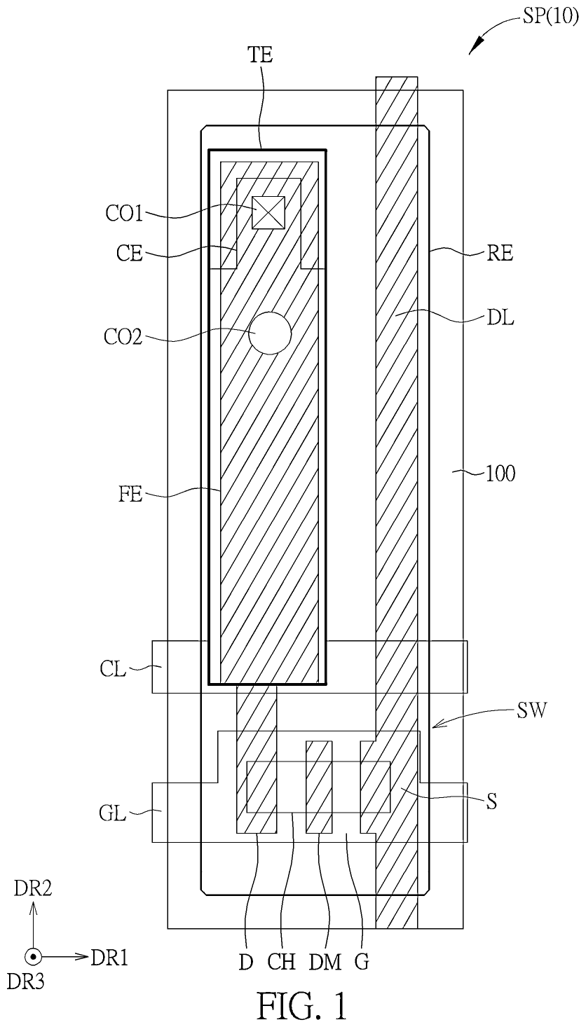

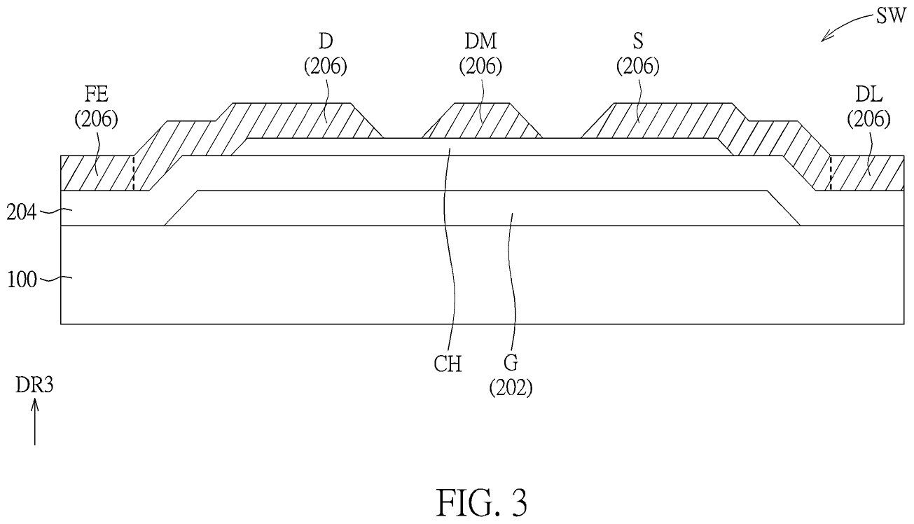

A direction DR1, a direction DR2, and a direction DR3 are shown in the following figures. The direction DR3 may be a normal direction or a top view direction. As shown in FIG. 3, the direction DR3 may be perpendicular to an upper surface of a substrate 100. As shown in FIG. 1, the direction DR1 and the direction DR2 may be horizontal directions and may be perpendicular to the direction DR3. The direction DR1 is different from the direction DR2. For example, the direction DR1 may be perpendicular to the direction DR2. The spatial relationship of structures can be described according to the directions DR1 and DR2 in the following drawings.

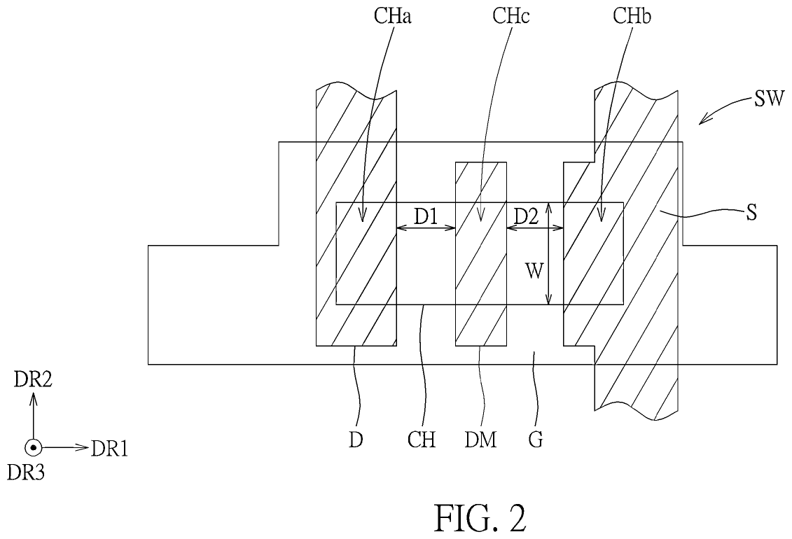

Refer to FIG. 1 to FIG. 3. FIG. 1 is a schematic diagram illustrating a top view of a sub-pixel of a display panel of the first embodiment of the present invention. FIG. 2 is a schematic diagram illustrating an enlarged view of a transistor of a display panel of the first embodiment of the present invention. FIG. 3 is a schematic diagram illustrating a cross-section view of a transistor of a display panel of the first embodiment of the present invention. The display panel of this embodiment takes reflective type or transflective type display panel for example, but the present invention is not limited thereto. As shown in FIG. 1, a display panel 10 includes the substrate 100, a scan line GL, and a data line DL. The substrate 100 may include a hard substrate, such as glass substrate, quartz substrate, or sapphire substrate, but not limited thereto. Alternatively, the substrate 100 may include a soft substrate, such as polyimide (PI) substrate or polyethylene terephthalate (PET) substrate, but not limited thereto.

The scan line GL and the data line DL are disposed on the substrate 100. The scan line GL extends along the direction DR1, and the data line DL extends along the direction DR2. A sub-pixel SP is disposed on the substrate 100 and may correspond to the scan line GL and the data line DL. Besides, the display panel 10 may include a plurality of the scan lines GL and a plurality of the data lines DL, wherein the scan lines GL and the data lines DL may intersect to form a plurality of the sub-pixels SP.

The sub-pixel SP includes a transistor SW, and the transistor SW is disposed on the substrate 100. The transistor SW may, for example, be a bottom-gate thin film transistor, but not limited thereto. The design concept of the present invention may further be applied to a top-gate thin film transistor. Besides, the transistor SW may be a low temperature poly-silicon (LTPS) thin film transistor, an indium gallium zinc oxide (IGZO) thin film transistor, or an amorphous silicon (a-Si) thin film transistor, but not limited thereto.

The transistor SW includes a gate G, a source S, a drain D, a semiconductor layer CH, and a gate insulation layer 204. The scan line GL is electrically connected to the gate G of the transistor SW, and a switching signal for controlling the transistor SW may be provided to the gate G of the transistor SW through the scan line GL, such that refreshing displayed images may be controlled. The data line DL is electrically connected to the source S of the transistor SW, and a gray-level signal of the displayed images may be provided to the source S of the transistor SW through the data line DL.

As shown in FIG. 3, the gate G is disposed on the substrate 100, the semiconductor layer CH is disposed on the gate G, and the gate insulation layer 204 is disposed between the gate G and the semiconductor layer CH. The source S and the drain D are disposed on the semiconductor layer CH. As shown in FIG. 2 and FIG. 3, the source S is disposed at one end of the semiconductor layer CH, and the drain D is disposed at another end of the semiconductor layer CH. As shown in FIG. 2, the source S is overlapped with a first region CHa of the semiconductor layer CH in the direction DR3, and the drain D is overlapped with a second region CHb of the semiconductor layer CH in the direction DR3.

The transistor SW further includes a dummy electrode DM. As shown in FIG. 3, the dummy electrode DM is disposed on the semiconductor layer CH, and the dummy electrode DM may be in direct contact with the semiconductor layer CH. As shown in FIG. 2, the dummy electrode DM is disposed between the source S and the drain D. The dummy electrode DM is separated from the source S, and the dummy electrode DM is separated from the drain D. In this embodiment, as shown in FIG. 2, the dummy electrode DM has a rectangular structure, and the dummy electrode DM is overlapped with a portion of the semiconductor layer CH, such as a third region CHc, in the direction DR3, but not limited thereto. Besides, the dummy electrode DM is electrically floating.

In the conventional transistors, the gate being off does not mean the current is completely off. There is still a portion of leakage path that causes electricity leakage of the transistor. According to the below Equation (1), the amount of electricity leakage is inversely proportional to a channel length of the transistor.

$${I}_{off} ( nA ) = 100 \cdot \frac{W}{L} \cdot {10}^{- \frac{{V}_{t}}{S}} \qquad ( 1 )$$

In Equation (1), I_{off} is the leakage current (unit is nanoampere, nA), W is the channel width, L is the channel length, Vₜ is the threshold voltage, and S is the subthreshold swing.

In the present invention, the dummy electrode DM disposed between the source S and the drain D may increase the channel length of the transistor SW. As the channel length of the transistor SW increases, the leakage path for electrons is elongated, such that electrons are hard to reach the electrode on the other side, which suppresses electricity leakage. As shown in FIG. 2, the dummy electrode DM disposed on the semiconductor layer CH has a distance D1 to the source S, and the dummy electrode DM disposed on the semiconductor layer CH has a distance D2 to the drain D. Sum of the distance D1 and the distance D2 is the channel length of the transistor SW.

In this embodiment, the distance D1 and the distance D2 may respectively be 4 micrometers, the channel length of the transistor SW may be 8 micrometers, and a channel width W of the transistor SW may be 17 micrometers, but not limited thereto. The distance D1 and the distance D2 may, for example, be measured in the direction DR1, and the channel width W may, for example, be measured in the direction DR2.

As shown in FIG. 2 and FIG. 3, the dummy electrode DM is overlapped with a portion of the semiconductor layer CH, such as the third region CHc, in the direction DR3. Therefore, the third region CHc of the semiconductor layer CH may be shielded by the dummy electrode DM, which reduces an exposed area of an upper surface of the semiconductor layer CH and mitigates light to be received by the upper surface of the semiconductor layer CH to produce the leakage current. In another aspect, the semiconductor layer CH is overlapped with the gate G in the direction DR3. Therefore, light emitting from a backlight module may be shielded by the gate G, which mitigates light to be received by a bottom surface of the semiconductor layer CH to produce the leakage current.

As shown in FIG. 1, the sub-pixel SP includes an electrode FE. The electrode FE is disposed on one side of the transistor SW and electrically connected to the drain D of the transistor SW. The sub-pixel SP further includes a transparent electrode TE (marked with thick black lines). The transparent electrode TE is disposed on the electrode FE and electrically connected to the electrode FE. For example, an insulation layer may be disposed between the transparent electrode TE and the electrode FE. The insulation layer may include a contact hole CO1, and the transparent electrode TE may be electrically connected to the electrode FE through the contact hole CO1, but not limited thereto.

The sub-pixel SP further includes a reflective electrode RE (marked with sub-thick black lines) disposed on the transparent electrode TE and electrically connected to the transparent electrode TE. For example, an insulation layer may be disposed between the reflective electrode RE and the transparent electrode TE. The insulation layer may include a contact hole CO2, and the reflective electrode RE may be electrically connected to the transparent electrode TE through the contact hole CO2, but not limited thereto. The reflective electrode RE, the transparent electrode TE, and the electrode FE are electrically connected to each other and are electrically connected to the drain D of the transistor SW together. Therefore, the reflective electrode RE, the transparent electrode TE, and the electrode FE may collectively serve as a pixel electrode.

In another words, the sub-pixel includes a pixel electrode. The pixel electrode is disposed on the substrate 100 and electrically connected to the drain D of the transistor SW. The pixel electrode includes the reflective electrode RE, the transparent electrode TE, and the electrode FE.

The sub-pixel SP further includes an electrode CE. The electrode CE is disposed between the electrode FE and the substrate 100. The display panel 10 further includes a common signal line CL. The common signal line CL extends along the direction DR1. The electrode CE is electrically connected to the common signal line CL, and the common signal line CL may provide a common voltage to the electrode CE.

In the present invention, although the transistor SW further includes the dummy electrode DM, the area of the transistor SW is not significantly increased, such that there is still enough area preserved in the sub-pixel SP for disposing the pixel electrode (e.g., the reflective electrode RE, the transparent electrode TE, and the electrode FE) and the common electrode (e.g., the electrode CE), and therefore the sub-pixel SP can store enough capacitance to prevent the display quality from being affected due to lack of capacitance during low frequency driving.

In another aspect, as shown in FIG. 3, the display panel 10 includes a conductive layer 202 and a conductive layer 206. The conductive layer 202 is disposed on the substrate 100, and the conductive layer 202 may include the scan line GL, the gate G of the transistor SW, the electrode CE, and the common signal line CL in FIG. 1, but not limited thereto. The gate insulation layer 204 is disposed on the conductive layer 202, and the semiconductor layer CH is disposed on the gate insulation layer 204. The conductive layer 206 is disposed on the semiconductor layer CH and the gate insulation layer 204, and the conductive layer 206 may include the data line DL, the electrode FE, and the source S, the drain D, and the dummy electrode DM of the transistor SW in FIG. 1, but not limited thereto. Therefore, the dummy electrode DM, the source S, and the drain D are formed of the same conductive layer 206, and materials of the dummy electrode DM, the source S, and the drain D are the same, but not limited thereto. In some embodiments, another conductive layer may be disposed on the conductive layer 206, and may be disposed between the conductive layer 206 and the transparent electrode TE, but not limited thereto.

The gate insulation layer 204 or other gate insulation layer(s) may include inorganic or organic insulation materials, but not limited thereto. The conductive layer 202 and the conductive layer 206 may include single metal layer, such as aluminum, copper, titanium, tungsten, etc., or composite metal layer, such as molybdenum/aluminum/molybdenum, titanium/aluminum/titanium, titanium/copper/titanium, titanium/copper, etc., but not limited thereto. The transparent electrode TE may include transparent materials, such as indium tin oxide (ITO), indium zinc oxide (IZO), or aluminum zinc oxide (AZO), but not limited thereto. The reflective electrode RE may include silver or other suitable reflective metal materials. The reflective electrode RE may also include single metal layer or composite metal layer, but not limited thereto.

The display panel of the present invention is not limited to the aforementioned embodiment. The following description continues to detail other embodiments. To simplify the description and show the difference between other embodiments and the above-mentioned embodiment, identical components in each of the following embodiments are marked with identical symbols, and the identical features will not be redundantly described.

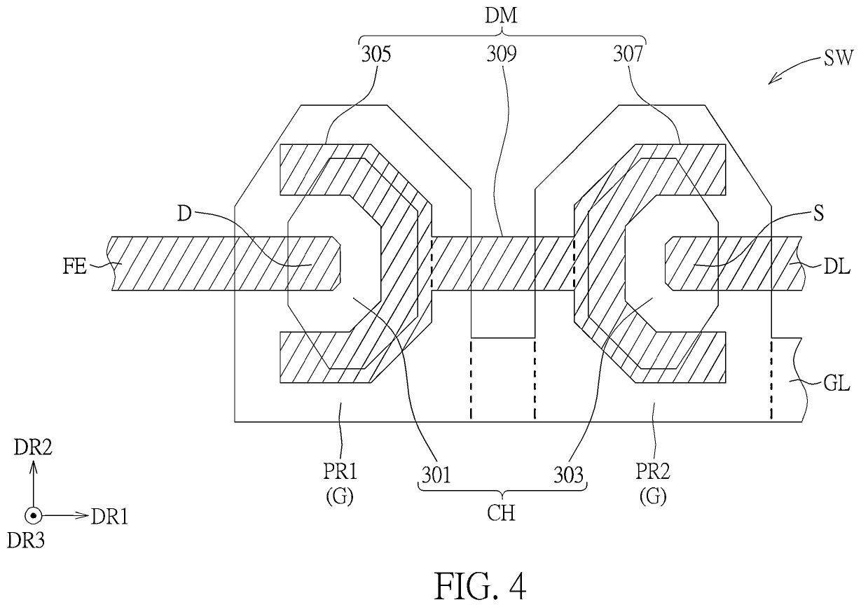

Refer to FIG. 4. FIG. 4 is a schematic diagram illustrating an enlarged view of a transistor of a display panel of the second embodiment of the present invention. In this embodiment, the gate G includes a protrusion PR1 and a protrusion PR2. The protrusion PR1 and the protrusion PR2 are arranged next to each other and electrically connected to each other. The semiconductor layer CH includes a first portion 301 and a second portion 303. The first portion 301 is disposed on the protrusion PR1 of the gate G, the second portion 303 is disposed on the protrusion PR2 of the gate G, and the first portion 301 is separated from the second portion 303.

The dummy electrode DM includes a first portion 305, a second portion 307, and a connecting portion 309. The first portion 305 of the dummy electrode DM is disposed at one end of the dummy electrode DM and adjacent to the drain D, and the first portion 305 is disposed on the first portion 301 of the semiconductor layer CH. Therefore, the first portion 301 of the semiconductor layer CH is disposed between the protrusion PR1 of the gate G and the first portion 305 of the dummy electrode DM.

The second portion 307 of the dummy electrode DM is disposed at another end of the dummy electrode DM and adjacent to the source S, and the second portion 307 is disposed on the second portion 303 of the semiconductor layer CH. Therefore, the second portion 303 of the semiconductor layer CH is disposed between the protrusion PR2 of the gate G and the second portion 307 of the dummy electrode DM.

The first portion 305 and the second portion 307 of the dummy electrode DM include a U-shaped structure respectively. An opening of the U-shaped structure of the first portion 305 and an opening of the U-shaped structure of the second portion 307 face opposite directions. At least a portion of the drain D may be disposed in the opening of the U-shaped structure of the first portion 305, and at least a portion of the source S may be disposed in the opening of the U-shaped structure of the second portion 307. Besides, the connecting portion 309 is disposed between the first portion 305 and the second portion 307, and the connecting portion 309 is connected to the first portion 305 and the second portion 307.

The dummy electrode DM of this embodiment may also provide the effect aforementioned in the first embodiment. Besides, as the first portion 305 and the second portion 307 of the dummy electrode DM include the U-shaped structures, the channel width of the transistor SW may be increased to enhance a charging efficiency of the transistor SW. In this embodiment, the source S and a portion of the data line DL connecting to the source S may have a smaller size (e.g., area) to reduce a parasitic capacitance between the data line DL and the scan line GL and to enhance the charging efficiency of the transistor SW. Besides, the drain D and a portion of the electrode FE of the pixel electrode connecting to the drain D may have a smaller size (e.g., area) to reduce electricity leakage of the storage capacitor.

In summary, in the display panel of the present invention, the transistor of the sub-pixel includes the dummy electrode, wherein the dummy electrode is disposed between the source and the drain, which may increase a channel length of the transistor to suppress electricity leakage. Besides, a portion of the semiconductor layer may be shielded by the dummy electrode to reduce the leakage current generated by the semiconductor layer receiving light. In some embodiments, as the dummy electrode includes the U-shaped structures, the charging efficiency of the transistor may be enhanced. In addition, although the transistor further includes the dummy electrode, the area of the transistor is not significantly increased. Thus, there is still enough area preserved in the sub-pixel for disposing the pixel electrode, such that the stored capacitance may be plentiful to prevent the display quality from being affected due to lack of capacitance during low frequency driving.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A display panel, comprising:
a substrate; and
a sub-pixel disposed on the substrate, wherein the sub-pixel comprises a transistor and the transistor comprises:
a gate disposed on the substrate;
a semiconductor layer disposed on the gate;
a source and a drain disposed on the semiconductor layer, wherein the source is disposed on one end of the semiconductor layer, and the drain is disposed on another end of the semiconductor layer; and
a dummy electrode disposed on the semiconductor layer and between the source and the drain, wherein the dummy electrode is separated from the source, the dummy electrode is separated from the drain, and the dummy electrode is electrically floating.

2. The display panel according to claim 1, wherein materials of the dummy electrode, the source, and the drain are the same.

3. The display panel according to claim 1, wherein the dummy electrode is overlapped with a portion of the semiconductor layer.

4. The display panel according to claim 1, wherein the dummy electrode is in direct contact with the semiconductor layer.

5. The display panel according to claim 1, wherein the dummy electrode has a rectangular structure.

6. The display panel according to claim 1, wherein the dummy electrode comprises:
a first portion disposed at one end of the dummy electrode and near the drain;
a second portion disposed at another end of the dummy electrode and near the source, the first portion and the second portion comprising a U-shaped structure respectively; and
a connecting portion disposed between the first portion and the second portion.

7. The display panel according to claim 6, wherein the semiconductor layer comprises:
a first portion disposed between the gate and the first portion of the dummy electrode; and
a second portion disposed between the gate and the second portion of the dummy electrode, wherein the first portion of the semiconductor layer and the second portion of the semiconductor layer are separated.

8. The display panel according to claim 1, wherein the sub-pixel comprises:
a scan line disposed on the substrate and electrically connected to the gate of the transistor;
a data line disposed on the substrate and electrically connected to the source of the transistor; and
a pixel electrode disposed on the substrate and electrically connected to the drain of the transistor.

9. The display panel according to claim 8, wherein the pixel electrode comprises:
an electrode disposed on one side of the transistor and electrically connected to the drain of the transistor;
a transparent electrode disposed on the electrode and electrically connected to the electrode; and
a reflective electrode disposed on the transparent electrode and electrically connected to the transparent electrode.

10. The display panel according to claim 1, wherein the transistor further comprises a gate insulation layer disposed between the gate and the semiconductor layer.
